(19) United States
(12) Patent Application Publication
(10) Pub. No.: US 2004/0198261 A1
(43) Pub. Date: Oct. 7, 2004

(54) Method of self-calibration in a wireless transmitter

(76) Inventor: Wei Xiong, San Diego, CA (US)

Correspondence Address: QUALCOMM Incorporated, Attn: Patent Department, 5775 Morehouse Drive, San Diego, CA, 92121-1714, US

(21) Appl. No.: 10/185,410

(22) Filed: Jun. 28, 2002

(51) Int. Cl. H04B 1/00; H04B 7/00; H03C 1/62; H04B 17/00; H04B 1/04; H01Q 11/12

(52) U.S. Cl. 455/115.1; 455/69; 455/127.1

(57) ABSTRACT

A method of self-calibration of a wireless LAN communication device includes entering a self-calibration mode when the device is powered up or commanded by software. A packet stream is transmitted at an initial transmit power level. The packet stream may comprise standard data packets. The transmit power level may be monitored from data packet to data packet; and adjusted in steps by setting a transmit gain using a control voltage adjustment determined according to a transmit gain variation so as to make the step size as large as possible without exceeding a predetermined maximum step size. The transmit power level is, thus, adjusted so as not to exceed a predetermined maximum allowable level. The transmit power level is then adjusted to a desired level. Lower desired transmit power levels may be set by shifting bits in a digital-to-analog converter and setting the transmit gain for a higher transmit power level.

### BACKGROUND

The present invention generally relates to wireless communication devices and, more particularly, to self-calibration of wireless transmitters for communication between a wireless device and an access point in a local area network (LAN).

Wireless communication devices, for example, devices using radio frequency signal transmission, generally must comply with regulations limiting the transmit power and emissions of the devices. Such regulations may be enforced by the Federal Communications Commission (FCC) in the United States, for example, or in Europe by the European Telecommunications Standards Institute (ETSI). Wireless LAN communication networks are subject, for example, to the 802.11b standard. The 802.11b standard limits transmit power for wireless LAN communication devices in the United States to 1000 milliwatts (or 30 dBm, i.e., decibels normalized to one milliwatt), in Europe to 100 milliwatts (or 20 dBm), and in Japan to 10 milliwatts per megaHertz (or 10 dBm/MHz), for example. Such wireless LAN communication devices typically may be found in laptop computers, cell phones, portable modems, or personal digital assistants (PDAs), where they are used for communication with a wired LAN through an access point, which may be briefly described as a wireless transmitter/receiver connected into the wired LAN for interfacing the wired LAN to the wireless communication devices.

In order to comply with standards and regulations for emission of signals and other radiation, wireless communication devices are usually calibrated in the factory before reaching the consumer. For example, calibration may be required to adjust each unit for proper operation at varying temperatures and to compensate for part-to-part variation between individual wireless communication devices. Besides the part-to-part variation, devices such as cell phones exhibit a large dynamic range in transmitted output power, which for a cell phone may be a range of 80-100 dB, for example. Because of the stringency of the requirements, the part-to-part variation, and the large dynamic range, high calibration accuracy is typically required so that each unit must be individually calibrated before leaving the factory, a time-consuming and relatively expensive process that increases the cost of each unit.

For wireless LAN communication devices, however, the emission limits of the 802.11b standard allow a dynamic range in transmission output power that is much smaller than is typically the case, for example, for cell phones. For example, no power control is needed to comply with the 802.11b standard as long as the maximum output power is below 20 dBm. In a typical application environment, the dynamic range needed in a wireless LAN device is usually 20 dBm. The overall variation in transmit power due to the various factors outlined above, however, may be relatively large by comparison. For example, the overall variation in a wireless communication device may cause a +/−17.3 dB variation in transmitter gain and output transmit power from unit to unit under varying conditions. Thus, a unit set to transmit at 10 dBm may actually, without calibration, transmit at over 27 dBm, saturating its power amplifier and exceeding the standard limits, or may transmit at −17.3 dBm when set to transmit at 0 dBm so that the receiver cannot “hear” the transmitted signal. Thus, it is feasible to use a less accurate and less expensive form of calibration for wireless LAN communication devices, but the calibration method used must be able to accurately compensate for relatively large variations in transmit power.

As can be seen, there is a need for calibration of wireless communication devices in which expensive individual factory calibration of each unit can be avoided. There is also a need for inexpensive calibration of wireless communication devices that is accurate enough to compensate for large transmit power gain variation from unit to unit.

### SUMMARY

In one aspect of the present invention, a method for self-calibration includes steps of: transmitting a transmit signal containing a packet stream at an initial transmit power level; monitoring a transmit power level of the transmit signal; adjusting the transmit power level of the transmit signal by a step size so as not to exceed a predetermined maximum allowable transmit power level; and adjusting the transmit power level to a desired transmit power level.

In another aspect of the present invention, a method of self-calibration of a wireless communication device includes steps of: determining a control voltage adjustment according to a transmit gain variation so as to make a step size as large as possible without exceeding a predetermined maximum step size; entering a self-calibration mode when the wireless communication device is powered up; transmitting a transmit signal containing a packet stream at an initial transmit power level; monitoring a transmit power level of the transmit signal; using the control voltage adjustment to adjust the transmit power level of the transmit signal by the step size so as not to exceed a predetermined maximum allowable transmit power level; and adjusting the transmit power level to a desired transmit power level.

In still another aspect of the present invention, a method of self calibration of a wireless LAN communication device for communication with an access point of a LAN, includes steps of: entering a self-calibration mode when the wireless LAN communication device is powered up; transmitting a transmit signal containing a packet stream at an initial transmit power level, wherein the packet stream comprises at least one packet and the transmit power level of the transmit signal is monitored subsequent to the transmission of each packet; monitoring a transmit power level of the transmit signal; adjusting the transmit power level of the transmit signal by a step size so as not to exceed a predetermined maximum allowable transmit power level; and adjusting the transmit power level to a desired transmit power level.

In yet another aspect of the present invention, a method of self calibration of a wireless LAN communication device for communication with an access point of a LAN, includes steps of: entering a self-calibration mode when the wireless LAN communication device is powered up; transmitting a transmit signal containing a packet stream at an initial transmit power level, wherein the packet stream comprises at least one standard data packet and the transmit power level of the transmit signal is monitored subsequent to the transmission of each standard data packet; monitoring a transmit power level of the transmit signal; adjusting the transmit power level of the transmit signal by a step size, wherein the adjusting is performed by setting a transmit gain using a control voltage adjustment determined according to a transmit gain variation so as to make the step size as large as possible without exceeding a predetermined maximum step size, whereby the transmit power level is adjusted so as not to exceed a predetermined maximum allowable transmit power level; and adjusting the transmit power level to a desired transmit power level, wherein the transmit power level is adjusted to a higher desired transmit power level by setting the transmit gain for the higher desired transmit power level, and wherein the transmit power level is adjusted to a lower desired transmit power level by shifting bits in a digital-to-analog converter and setting the transmit gain for a higher transmit power level.

These and other features, aspects and advantages of the present invention will become better understood with reference to the following drawings, description and claims.

### BRIEF DESCRIPTION OF THE DRAWINGS

FIG. 1 is a block diagram of one example of wireless communication device configured to use self-calibration in accordance with one embodiment of the present invention; and

FIG. 2 is a flow chart illustrating one example of a procedure for self-calibration of a wireless communication device, such as the device shown in FIG. 1, in accordance with one embodiment of the present invention.

### DETAILED DESCRIPTION

The following detailed description is of the best currently contemplated modes of carrying out the invention. The description is not to be taken in a limiting sense, but is made merely for the purpose of illustrating the general principles of the invention, since the scope of the invention is best defined by the appended claims.

An embodiment of the present invention provides for calibration of wireless communication devices in which expensive individual factory calibration of each unit can be avoided. One example of wireless communication devices that could benefit from application of the present invention is wireless LAN communication devices that may typically be found in laptop computers, cell phones, portable modems, or personal digital assistants (PDAs), where they are used for communication with a wired LAN through an access point subject to the 802.11b standard. In one embodiment, the present invention avoids expensive individual factory calibration of each unit by using self-calibration. Self-calibration can be implemented, for example, by software programmed into a processor used by the communication device. As another example, self-calibration can be implemented directly in hardware, such as the digital signal processing (DSP) subsystem of the device. So, for example, the first time a user, such as the product consumer, powers on the unit, the unit automatically calibrates itself so that expensive individual factory calibration of each unit is eliminated—only certain basic adjustments and quality control would need to be performed at the factory.

An embodiment of the present invention also provides for inexpensive calibration of wireless communication devices that is accurate enough to compensate for large transmit power gain variations, due, for example, to component differences from unit to unit, i.e., part-to-part variation, and varying conditions such as transmit frequency, supply voltage, and ambient temperature. In one embodiment, sufficient accuracy is achieved by adjusting the calibration in steps, rather than all at once, as further described below.

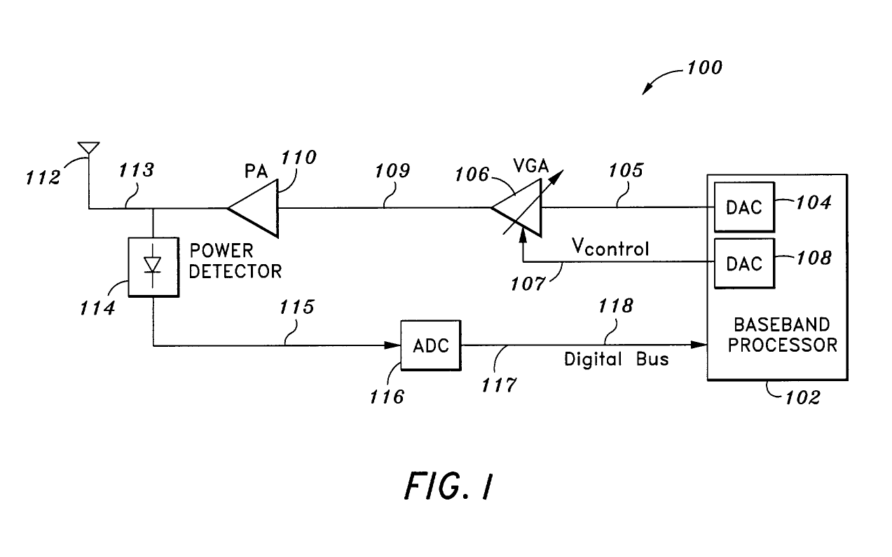

Referring now to FIG. 1, an exemplary transmitter 100 of a wireless communication device in which self-calibration of transmit power can be practiced according to one embodiment is illustrated. Transmitter 100 may include baseband processor 102. Baseband processor 102 may perform a great number of functions, as known in the art. For example, baseband processor 102 may buffer data and format the data into data packets, process various communication protocols, and produce a digital output packet stream that is fed to digital-to-analog converter (DAC) 104, which may be included in baseband processor 102 as depicted in FIG. 1. DAC 104 may produce a baseband signal 105 for transmitting the packet stream. Baseband signal 105 may be used to modulate a radio frequency (RF) carrier.

Baseband signal 105 may be fed to variable gain amplifier 106. The gain of variable gain amplifier may be controlled by a control voltage, Vcontrol voltage 107. Vcontrol voltage 107 may be output by DAC 108, which may be included in baseband processor 102 as depicted in FIG. 1. Thus, baseband processor 102 may provide a digital control signal to DAC 108, which in turn converts the digital control signal to Vcontrol voltage 107, for controlling the gain of variable gain amplifier 106. By controlling the gain of variable gain amplifier 106, the power of variable gain amplifier output signal 109 may be adjusted. Variable gain amplifier output signal 109, containing the packet stream, can be fed to power amplifier 110. Power amplifier 110 can amplify signal 109 for transmission via antenna 112 as a radio, or wireless, transmit signal 113 containing the packet stream. Hence, adjusting the output power of signal 109 can ultimately adjust the output transmit power of transmitter 100 at antenna 112. Thus, controlling the gain of variable gain amplifier 106 may be used for a number of purposes, including controlling the level of output transmit power of transmitter 100 to comply with various standards and regulations, such as the 802.11b standard.

In order to provide self-calibration of the output transmit power of transmitter 100, some means of monitoring or sensing the output transmit power may be required. As seen in FIG. 1, power detector 114 may be provided to measure the power of transmit signal 113. Power detector 114 may comprise, for example, a diode detector and appropriate circuitry known in the art for converting the power level of transmit signal 113 at antenna 112 to a measurement voltage 115. Measurement voltage 115 may be fed to analog-to-digital converter (ADC) 116. ADC 116 can convert the level of measurement voltage 115 to a digital value 117 representing the output transmit power of transmit signal 113 of transmitter 100 and can feed digital value 117 over digital bus 118 to baseband processor 102. Thus, baseband processor 102 may use the information contained in digital value 117 about the transmit power of transmitter 100, in accordance with the invention, to provide a control signal to DAC 108 for controlling the gain of variable gain amplifier 106, and thereby the output power level of transmit signal 113 at antenna 112, i.e., the transmit power of transmitter 100.

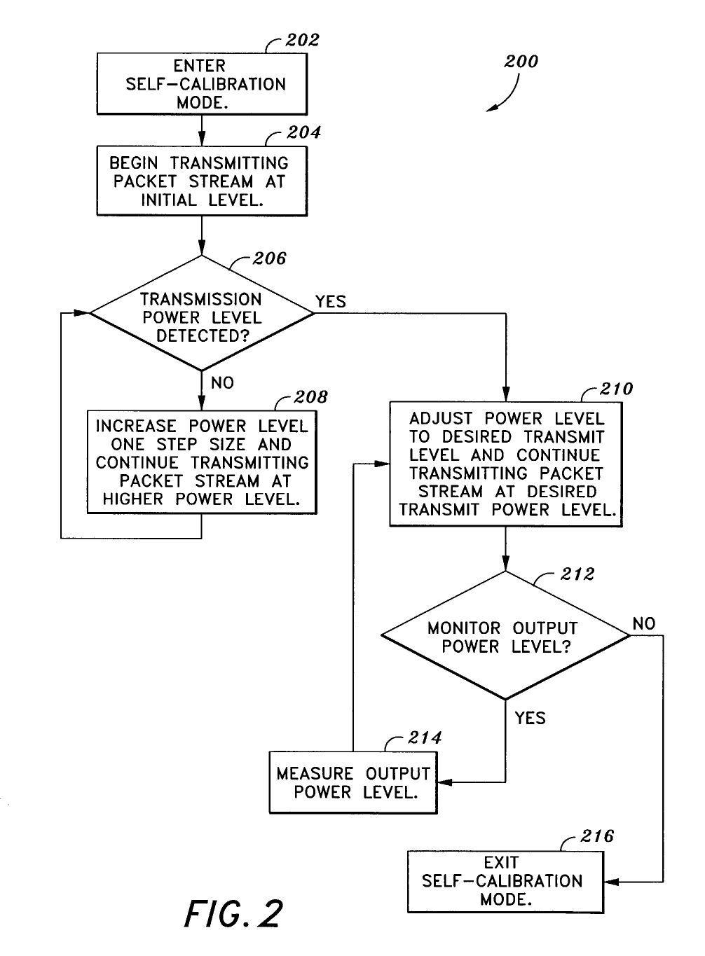

Referring now to FIG. 2, an exemplary embodiment of a process 200 for self-calibration of the transmit power of a wireless communication device, such as transmitter 100 shown in FIG. 1, is illustrated. Process 200 may be implemented, for example, in software loaded in a memory in baseband processor 102 of transmitter 100. Process 200 may also be implemented, for example, in hardware, such as a DSP module, contained in baseband processor 102 of transmitter 100.

Exemplary process 200 may include steps 202, 204, 206, 208, 210, 212, 214, and 216, which conceptually break up process 200 for purposes of conveniently illustrating process 200 according to one embodiment, but which do not necessarily uniquely characterize process 200. In other words, process 200 could be implemented by different steps in different orders from that shown in FIG. 2 and still achieve the self-calibration of a wireless communication device in accordance with the invention. Exemplary process 200 is illustrated with reference to self-calibration of an exemplary wireless communication device including transmitter 100 shown in FIG. 1.

Process 200 may begin with step 202, in which the wireless communication device enters self-calibration mode. For example, the wireless communication device may enter self-calibration mode upon power up of the device, or upon the device changing channels. The device may also enter self-calibration mode, for example, for purposes of compensating for ambient temperature changes. Because such ambient temperature changes generally occur relatively slowly over time, compensating for ambient temperature changes might be accomplished, for example, by the device entering self-calibration mode periodically at pre-determined intervals of time or, as another example, in response to a large enough change in temperature sensed by a temperature sensor. The device may also enter self-calibration mode, for example, for the purpose of compensating for supply voltage changes. Once the device enters self-calibration mode, process 200 may continue at step 204

At step 204, transmitter 100 of the device may begin transmitting transmit signal 113 containing a packet stream. The first packet of the packet stream may be a “null” packet containing no information, but which conforms, for example, to the 802.11b standard requirements for a data packet. In a first option, adjustments to the transmit power level of transmitter 100 may be made while the first null packet is being transmitted. In a second option, adjustments to the transmit power level of transmitter 100 may be made from packet to packet, i.e., after the transmission of the first and each subsequent null packet until the appropriate transmit power level is achieved. Alternatively, the first packet of the packet stream may also be a standard data packet containing information and conforming, for example, to the 802.11b standard requirements for a data packet. In a third option, adjustments to the transmit power level of transmitter 100 may be made while the first standard data packet is being transmitted. In a fourth option, adjustments to the transmit power level of transmitter 100 may be made from packet to packet, i.e., after the transmission of the first and each subsequent standard data packet until the appropriate transmit power level is achieved.

Each option has certain advantages and disadvantages. For example, the first and third options require fast adjustments to the transmit power level and may, therefore, require the self-calibration process 200 to be implemented in hardware. Hardware implementation may, for example, have greater initial cost of implementation and may provide less flexibility for modifications to the implementation. Also, for example, the second and fourth options may be implemented using software, which may provide greater flexibility and lower cost, but for which adjustments to power level may be performed more slowly.

Transmission of transmit signal 113 may begin at a pre-determined initial power level. For the example of a wireless communication device with +/−17.3 dB transmit power variation, initial transmit power level can be set below 2.7 dBm to protect against possible first transmission power level being greater than 20 dBm. Conversely, due to the +/−17.3 dB variation, an attempt to transmit at an initial power level of 2.7 dBm may result in an initial transmission as low as −14.6 dBm. In the present example of a wireless communication device with +/−17.3 dB transmit power variation, used to illustrate one embodiment, the minimum transmit power level that can be detected by power detector 114 is a transmit power level of 10 dBm. Thus, due to the +/−17.3 dB transmit power variation, in order to achieve a transmit power level that can be detected by power detector 114, an adjustment or increase to the initial transmit power level may or may not be required to reach a desired transmit output power level of 20 dBm. Therefore, after the initial transmission of the packet stream, which may be a portion of a single packet or an entire packet, according to the options described above, control of process 200 may be passed to step 206.

At step 206, the transmit power level can be monitored. Transmit power level may be monitored at least as often as adjustments are made to the transmit power level. For example, monitoring may occur within packets, or from packet to packet according to which of the four options described above may be practiced. For example, the transmit power level may be measured by power detector 114, producing a measurement voltage 115 proportional to the transmit power level. Measurement voltage 115 may be fed through ADC 116, producing a digital value indicating whether the transmit power is high enough for power detector 114 to measure, and if high enough, what the transmit power level is. If the transmit power level is high enough to be measured, control of process 200 may be passed to step 210. If the transmit power level is not high enough to be measured, control of process 200 may be passed to step 208.

At step 208, transmit power level can be increased in order to eventually achieve a transmit power level high enough to be measured by power detector 114. The adjustment to transmit power should not, however, cause transmit power to exceed the maximum allowable emissions under the applicable standard, for example the 802.11b standard. In the present example used to illustrate one embodiment, the minimum transmit power level that can be detected by power detector 114 is a transmit power level of 10 dBm and the maximum desired transmit power level is 20 dBm. By adjusting the power level in discrete-sized steps, the power level can be adjusted upward without risk of exceeding the maximum allowable emissions. It is desirable to use the fewest number of steps to adjust the power quickly, so it is desirable to for the step size to be as large as possible. In the present example used to illustrate one embodiment, then, an ideal step size for increasing the transmit power level in steps may be approximately 10 dBm. For example, the value of Vcontrol voltage 107 may be adjusted by an appropriate amount to increase the gain of variable gain amplifier 106 by 10 dBm.

In the present example used to illustrate one embodiment, the part-to-part variation in components leads to an overall variation in the response of variable gain amplifier 106 to Vcontrol voltage 107. In the exemplary device, for each 1 percent of the supply voltage, Vdd, that Vcontrol voltage 107 is adjusted, the response of variable gain amplifier 106 may vary between 0.74 and 1.23 dBm/% Vdd. Thus, for a 10 dBm step size:

10 dBm*(0.01*Vdd/1.23 dBm)=0.0813*Vdd.

In other words, an adjustment to Vcontrol voltage 107 of approximately 8% of Vdd produces the 10 dBm step size in a device exhibiting the maximum variation. It is unknown, however, whether any given device will exhibit the maximum or the minimum variation. For a device exhibiting the minimum variation, the same 8% of Vdd adjustment to Vcontrol voltage 107 produces:

0.0813*Vdd*(0.74 dBm/0.01*Vdd)=6 dBm.

Thus, in the present example, ensuring that the step size does not exceed a maximum of 10 dBm, because of the particular minimum and maximum, respectively, variation values of 0.74 and 1.23 dBm/% Vdd, forces a minimum step size of approximately 6 dBm. Furthermore, due to the finite resolution of DAC 108, which provides Vcontrol voltage 107, the actual step size achieved may vary from the nominal step sizes of between 10 dBm and 6 dBm given in this example by an amount that depends on the resolution of DAC 108.

Continuing with the present example, in the case of an initial transmit power of −14.6 dBm, as described above, an adjustment of 24.6 dBm may be required to reach the minimum 10 dBm transmit power level required for detection by power detector 114. Thus, when the step size varies close to its minimum of 6 dBm, i.e., less than 6.15 dBm, a 24.6 dBm adjustment can be achieved in no fewer than 5 steps. As the step size varies closer to 10 dBm, due to the variation in conditions and between units, fewer steps may be required to achieve power detection by power detector 114. Therefore, 5 steps can be the worst case or maximum number of steps needed to reach power level detection by power detector 114.

Once transmit power level has been detected, control can be passed from step 208 to step 210 of process 200. As described above, transmit power level may be detected immediately after initial transmission, in which case process 200 passes to step 210 without processing step 208, or step 208 may be processed any number of times from one time to a worst case of five times, in the present example, before process 200 passes to step 210.

At step 210, the transmit power level is known so that an exact adjustment, within the resolution of DAC 108, may be made to bring the power level to the desired transmit power level. For example, power detector 114 may convert the transmit power level at antenna 112 to a measurement voltage 115. Measurement voltage 115 may be converted by ADC 116 to a digital value 117 representing the transmit power level of transmitter 100. Digital value 117 may be used by baseband processor 102 to provide a control signal to DAC 108 for controlling the gain of variable gain amplifier 106, and thereby the transmit power level of transmitter 100. For example, if the desired transmit power level is 20 dBm, baseband processor 102 may provide an appropriate control signal to DAC 108 so that Vcontrol voltage 107 is adjusted by an appropriate amount, in a manner similar to that described above, so that the gain of variable gain amplifier 106 can be increased to make up the difference between the detected transmit power level and the desired transmit power level. Also, for example, if the desired transmit power level is 10 dBm, baseband processor 102 may provide an appropriate control signal to DAC 108 so that Vcontrol voltage 107 is adjusted by an appropriate amount so that the gain of variable gain amplifier 106 is decreased to eliminate any difference between the detected transmit power level and the desired transmit power level.

As a further example, if the desired transmit power level is 0 dBm, baseband processor 102 may provide an appropriate control signal to DAC 108 so that Vcontrol voltage 107 is adjusted by an appropriate amount so that the gain of variable gain amplifier 106 is decreased to reduce the transmit power level to the desired transmit power level. For example, baseband processor 102 may provide the appropriate control signal to DAC 108 by linearly extrapolating the characteristics used to make adjustments between 10 dBm and 20 dBm. The efficiency of the linear extrapolation could be improved by using a linearizer table loaded in a memory in baseband processor 102.

An alternative method for providing desired transmit power levels at low levels of power involves using DAC 104 in addition to DAC 108. For example, DAC 104 may have 10 bits, and only 8 bits may be needed to process the baseband signal. Then, at the 20 dBm and 10 dBm power levels the baseband signal can be processed using the upper 8 bits of DAC 104 and the calibration results. For lower power levels, baseband processor 102 can shift the bits down by 2 in DAC 104 to use the lower 8 bits, effectively reducing output power by 12 dB. So, for example, for −2 dBm transmit power level, baseband processor 102 may set the transmit gain, using DAC 108, Vcontrol voltage 107, and variable gain amplifier 106, to be the same as the transmit gain for the 10 dBm transmit power level, and use the lower 8 bits of DAC 104.

Furthermore, the worst case number of steps required for power level adjustment may be reduced by adding a temperature, supply voltage, and frequency lookup. The improvement may involve steps 204 and 208 of process 200. The improvement relies on the observation that overall gain variations may be caused by: temperature, supply voltage, and frequency variations, and part-to-part variations between units. The first three variations are time-varying, whereas part-to-part variation is time-independent. In the present example of a wireless communication device with +/−17.3 dB overall transmit power variation, part-to-part variation is +/−7.4 dB, and the combined variation for temperature, supply voltage, and frequency is +/−9.9 dB. By compensating for the part-to-part variation, overall variation becomes +/−9.9 dB so that initial transmit power level can be set below 10.1 dBm at step 204 to protect against possible first transmission power level being greater than 20 dBm. Thus, the worst case or maximum number of power adjustment steps required at step 208 may be reduced to 2 steps in the present example used to illustrate one embodiment.

In the factory, some basic functional tests generally must be performed. Performing these functions tests would require the device to be turned on. Once the device is powered on, self-calibration can be performed. The temperature, supply voltage and frequency are all nominal. The error measured during calibration is then due to part-to-part variation. The error value due to part-to-part variation may be saved in a lookup table. Then, all gain control may be offset with this error value to compensate for the part-to-part variation. The variation is thereby reduced to +/−9.9 dB from +/−17.3 dB, and the worst case is reduced from 5 steps to 2 steps at step 208, or from a total of 6 power level adjustments to a total of 3 power level adjustments considering step 210. Thus, for the cost of a stored value, the self-calibration time may be reduced to approximately half that without the stored value.

In addition, the device may measure the temperature, the supply voltage and the frequency each time the calibration is executed. The device may then store the temperature, the supply voltage, and the frequency in conjunction with the error in the output power level. With sufficient stored data points, the device may extrapolate a set of curves that correlates the error in the output power level, the temperature, the supply voltage, and the frequency. Thus, the device may use this set of curves to predict the error in the output power at any given temperature, supply voltage, or frequency—or using any combination thereof, further decreasing the number of steps required to reach the desired output power level.

Process 200 may proceed directly to step 216 subsequent to performing step 210 if it is desirable to end self calibration. Alternatively, process 200 may include steps 212 and 214 if it is desirable to provide an option whether or not to monitor output power level during continued operation of transmitter 100. At step 212, process 200 determines whether output power level is to be monitored. For example, an option to either monitor or not monitor output power level may be set in software in baseband processor 102. Also the option could be determined by hardware or firmware in transmitter 100, for example, by setting a switch to either option. For example, the switch could be implemented within the circuitry of transmitter 100, could be implemented as an EPROM setting, or could be implemented as a jumper on a circuit board. If output power level is to be monitored, process 200 may proceed to step 214. If output power level is not to be monitored, process 200 may proceed to step 216.

At step 214, process 200 may measure output power level. For example, as described above, the transmit power level may be measured by power detector 114, producing a measurement voltage 115 proportional to the transmit power level. Measurement voltage 115 may be fed to ADC 116. ADC 116 may convert the level of measurement voltage 115 to a digital value 117 representing the output transmit power of transmit signal 113 of transmitter 100. This conversion may occur once every data packet, several times during a data packet, or continuously. ADC 116 can feed digital value 117 over digital bus 118 to baseband processor 102. Baseband processor 102 may read digital voltage 117 once every data packet, several times during a data packet, or continuously. Control of process 200 then may pass to step 210. At step 210, baseband processor 102 may use the information contained in digital value 117 about the transmit power of transmitter 100, in accordance with the invention, to provide a control signal to DAC 108 for controlling the gain of variable gain amplifier 106, and thereby control the output power level of transmit signal 113 at antenna 112, i.e., the transmit power of transmitter 100.

Process 200 may end with step 216, in which the wireless communication device may exit self-calibration mode and may continue transmitting without performing self-calibration processing steps of process 200.

It should be understood, of course, that the foregoing relates to preferred embodiments of the invention and that modifications may be made without departing from the spirit and scope of the invention as set forth in the following claims.

We claim:

1. A method for self-calibration comprising steps of:
transmitting a transmit signal containing a packet stream at an initial transmit power level;
monitoring a transmit power level of said transmit signal;
adjusting said transmit power level of said transmit signal by a step size so as not to exceed a predetermined maximum allowable transmit power level; and
adjusting said transmit power level to a desired transmit power level.

2. The method of claim 1, further comprising a step of determining a control voltage adjustment according to a transmit gain variation so as to make said step size as large as possible without exceeding a predetermined maximum step size.

3. The method of claim 2 wherein said transmit gain variation comprises a part-to-part variation.

4. The method of claim 2 wherein said transmit gain variation comprises a variation due to changes in transmit frequency.

5. The method of claim 2 wherein said transmit gain variation comprises a supply voltage variation.

6. The method of claim 2 wherein said transmit gain variation comprises a variation due to changes in ambient temperature.

7. The method of claim 1 wherein said packet stream comprises at least one packet and said transmit power level of said transmit signal is monitored while said packet is being transmitted.

8. The method of claim 1 wherein said packet stream comprises a plurality of packets and said transmit power level of said transmit signal is monitored from packet to packet.

9. The method of claim 1 wherein said packet stream comprises an initially transmitted packet and said initially transmitted packet is a null packet.

10. The method of claim 1 wherein said packet stream comprises an initially transmitted packet and said initially transmitted packet is a standard data packet.

11. The method of claim 1 wherein said transmit power level is adjusted to a desired transmit power level by linear extrapolation using a linearizer table.

12. The method of claim 1 wherein said transmit power level is adjusted to a lower desired transmit power level by shifting bits in a digital-to-analog converter and setting a transmit gain for a higher transmit power level.

13. The method of claim 1 wherein an error value is saved in a lookup table and a gain control is offset with said error value to compensate for a part-to-part variation, thereby reducing a worst case number of times said step of adjusting said transmit power level of said transmit signal by a step size is performed.

14. The method of claim 1, further comprising a step of entering a self-calibration mode when a wireless communication device is powered up and periodically at a predetermined time interval thereafter.

15. The method of claim 1, further comprising a step of exiting a self-calibration mode after said step of adjusting said transmit power level to a desired transmit power level.

16. The method of claim 1 wherein said predetermined maximum allowable transmit power level is in accordance with an 802.11b standard.

17. A method of self-calibration of a wireless communication device comprising steps of:
determining a control voltage adjustment according to a transmit gain variation so as to make a step size as large as possible without exceeding a predetermined maximum step size;
entering a self-calibration mode when said wireless communication device is powered up;
transmitting a transmit signal containing a packet stream at an initial transmit power level;
monitoring a transmit power level of said transmit signal;
using said control voltage adjustment to adjust said transmit power level of said transmit signal by said step size so as not to exceed a predetermined maximum allowable transmit power level; and
adjusting said transmit power level to a desired transmit power level.

18. The method of claim 17 wherein said packet stream comprises a packet and said transmit power level of said transmit signal is monitored while said packet is being transmitted.

19. The method of claim 17 wherein said packet stream comprises a plurality of packets and said transmit power level of said transmit signal is monitored from packet to packet.

20. The method of claim 17 wherein said packet stream comprises an initially transmitted packet and said initially transmitted packet is a null packet.

21. The method of claim 17 wherein said packet stream comprises an initially transmitted packet and said initially transmitted packet is a standard data packet.

22. The method of claim 17 wherein said transmit power level is adjusted to a desired transmit power level by linear extrapolation using a linearizer table.

23. The method of claim 17 wherein said transmit power level is adjusted to a lower desired transmit power level by shifting bits in a digital-to-analog converter and setting a transmit gain for a higher transmit power level.

24. The method of claim 17 wherein an error value is saved in a lookup table and a gain control is offset with said error value to compensate for a part-to-part variation, thereby reducing a worst case number of times said step of adjusting said transmit power level of said transmit signal by a step size is performed.

25. The method of claim 17, further comprising a step of exiting a self-calibration mode after said step of adjusting said transmit power level to a desired transmit power level.

26. The method of claim 17 wherein said predetermined maximum allowable transmit power level is in accordance with an 802.11b standard.

27. A method of self-calibration of a wireless LAN communication device for communication with an access point of a LAN, comprising steps of:
entering a self-calibration mode when said wireless LAN communication device is powered up;
transmitting a transmit signal containing a packet stream at an initial transmit power level, wherein said packet stream comprises at least one packet;
monitoring a transmit power level of said transmit signal, wherein said transmit power level of said transmit signal is monitored from packet to packet;
adjusting said transmit power level of said transmit signal by a step size so as not to exceed a predetermined maximum allowable transmit power level; and
adjusting said transmit power level to a desired transmit power level.

28. The method of claim 27, further comprising a step of determining a control voltage adjustment according to a transmit gain variation so as to make said step size as large as possible without exceeding a predetermined maximum step size.

29. The method of claim 27 wherein said packet stream comprises an initially transmitted packet and said initially transmitted packet is a null packet.

30. The method of claim 27 wherein said packet stream comprises an initially transmitted packet and said initially transmitted packet is a standard data packet.

31. The method of claim 27 wherein said transmit power level is adjusted to a lower desired transmit power level by shifting bits in a digital-to-analog converter and setting a transmit gain for a higher transmit power level.

32. The method of claim 27 wherein an error value is saved in a lookup table and a gain control is offset with said error value to compensated for a part-to-part variation, thereby reducing a worst case number of times said step of adjusting said transmit power level of said transmit signal by a step size is performed.

33. The method of claim 27, further comprising a step of exiting a self-calibration mode after said step of adjusting said transmit power level to a desired transmit power level.

34. The method of claim 27 wherein said predetermined maximum allowable transmit power level is in accordance with an 802.11b standard.

35. A method of self-calibration of a wireless LAN communication device for communication with an access point of a LAN, comprising steps of:
entering a self-calibration mode when said wireless LAN communication device is powered up;
transmitting a transmit signal containing a packet stream at an initial transmit power level, wherein said packet stream comprises at least one standard data packet;
monitoring a transmit power level of said transmit signal, wherein said transmit power level of said transmit signal is monitored from packet to packet.
adjusting said transmit power level of said transmit signal by a step size, wherein said adjusting is performed by setting a transmit gain using a control voltage adjustment determined according to a transmit gain variation so as to make said step size as large as possible without exceeding a predetermined maximum step size, whereby said transmit power level is adjusted so as not to exceed a predetermined maximum allowable transmit power level in accordance with a 802.11b standard; and
adjusting said transmit power level to a desired transmit power level, wherein said transmit power level is adjusted to a higher desired transmit power level by setting said transmit gain for said higher desired transmit power level, and wherein said transmit power level is adjusted to a lower desired transmit power level by shifting bits in a digital-to-analog converter and setting said transmit gain for a higher transmit power level.

36. The method of claim 35 wherein an error value is saved in a lookup table and a gain control is offset with said error value to compensated for a part-to-part variation, thereby reducing a worst case number of times said step of adjusting said transmit power level of said transmit signal by a step size is performed.

37. A transmitter comprising:
a variable gain amplifier having a gain controlled by a control voltage;
a power detector for monitoring a transmit power level of said transmitter and converting said transmit power level to a measurement voltage;
an analog-to-digital converter for converting said measurement voltage to a digital value;
a baseband processor, said baseband processor receiving said digital value and producing said control voltage while providing an output signal comprising a packet stream to said variable gain amplifier, wherein said baseband processor adjusts said control voltage during transmission of said packet stream, said control voltage effecting an adjustment to said transmit power level via said variable gain amplifier, said adjustment made from an initial transmit power level by a step size so as not to exceed a predetermined maximum allowable transmit power level; and wherein said baseband processor adjusts said control voltage so as to adjust said transmit power level to a desired transmit power level.

38. The transmitter of claim 37, wherein said adjustment is determined according to a transmit gain variation so as to make said step size as large as possible without exceeding a predetermined maximum step size.

39. The transmitter of claim 38 wherein said transmit gain variation comprises a part-to-part variation.

40. The transmitter of claim 38 wherein said transmit gain variation comprises a variation due to changes in transmit frequency.

41. The transmitter of claim 38 wherein said transmit gain variation comprises a supply voltage variation.

42. The transmitter of claim 38 wherein said transmit gain variation comprises a variation due to changes in ambient temperature.

43. The transmitter of claim 37 wherein an error value is saved in a lookup table and a gain control is offset with said error value to compensate for a part-to-part variation, thereby reducing a worst case number of times said adjustment to said transmit power level by a step size is made.

44. The transmitter of claim 37 wherein said predetermined maximum allowable transmit power level is in accordance with an 802.11b standard.

45. The transmitter of claim 37 wherein said transmit power level is adjusted to a lower desired transmit power level by shifting bits in a digital-to-analog converter and setting a transmit gain for a higher transmit power level.

46. The transmitter of claim 37 wherein said packet stream comprises at least one packet and said control voltage is adjusted while said packet is being transmitted.

47. The transmitter of claim 37 wherein said packet stream comprises a plurality of packets and said control voltage is adjusted from packet to packet.

48. The transmitter of claim 37 wherein said packet stream comprises an initially transmitted packet and said initially transmitted packet is a null packet.

49. The transmitter of claim 37 wherein said packet stream comprises an initially transmitted packet and said initially transmitted packet is a standard data packet.

50. The transmitter of claim 37 wherein said transmit power level is adjusted to a desired transmit power level by linear extrapolation using a linearizer table.

51. A wireless communication device comprising a transmitter and a receiver, said transmitter comprising:
a variable gain amplifier having a gain controlled by a control voltage;
a power detector for monitoring a transmit power level of said transmitter and converting said transmit power level to a measurement voltage;
an analog-to-digital converter for converting said measurement voltage to a digital value;
a baseband processor, said baseband processor receiving said digital value and producing said control voltage while providing an output signal comprising a packet stream to said variable gain amplifier, wherein said baseband processor adjusts said control voltage during transmission of said packet stream, said control voltage effecting an adjustment to said transmit power level via said variable gain amplifier, said adjustment made from an initial transmit power level by a step size so as not to exceed a predetermined maximum allowable transmit power level; and wherein said baseband processor adjusts said control voltage so as to adjust said transmit power level to a desired transmit power level.

52. The wireless communication device of claim 51, wherein said adjustment is determined according to a transmit gain variation so as to make said step size as large as possible without exceeding a predetermined maximum step size.

53. The wireless communication device of claim 52 wherein said transmit gain variation comprises a part-to-part variation.

54. The wireless communication device of claim 53 wherein an error value is saved in a lookup table and a gain control is offset with said error value to compensate for a part-to-part variation, thereby reducing a worst case number of times said adjustment to said transmit power level by a step size is made.

55. The wireless communication device of claim 51 wherein said predetermined maximum allowable transmit power level is in accordance with an 802.11b standard.

56. The wireless communication device of claim 51 wherein said transmit power level is adjusted to a lower desired transmit power level by shifting bits in a digital-to-analog converter and setting a transmit gain for a higher transmit power level.

57. The wireless communication device of claim 51 wherein said packet stream comprises a plurality of packets and said control voltage is adjusted from packet to packet.

58. A communication system comprising:
a local area network having an access point;
a wireless communication device for communication with said local area network via said access point, wherein said wireless communication device comprises a transmitter and a receiver, said transmitter comprising:
a variable gain amplifier having a gain controlled by a control voltage;
a power detector for monitoring a transmit power level of said transmitter and converting said transmit power level to a measurement voltage;
an analog-to-digital converter for converting said measurement voltage to a digital value;
a baseband processor, said baseband processor receiving said digital value and producing said control voltage while providing an output signal comprising a packet stream to said variable gain amplifier, wherein said baseband processor adjusts said control voltage during transmission of said packet stream, said control voltage effecting an adjustment to said transmit power level via said variable gain amplifier, said adjustment made from an initial transmit power level by a step size so as not to exceed a predetermined maximum allowable transmit power level; and wherein said baseband processor adjusts said control voltage so as to adjust said transmit power level to a desired transmit power level.

59. The communication system of claim 58, wherein said adjustment is determined according to a transmit gain variation so as to make said step size as large as possible without exceeding a predetermined maximum step size.

60. The communication system of claim 59 wherein said transmit gain variation comprises a part-to-part variation.

61. The communication system of claim 60 wherein an error value is saved in a lookup table and a gain control is offset with said error value to compensate for a part-to-part variation, thereby reducing a worst case number of times said adjustment to said transmit power level by a step size is made.

62. The communication system of claim 58 wherein said predetermined maximum allowable transmit power level is in accordance with an 802.11b standard.

63. The communication system of claim 58 wherein said transmit power level is adjusted to a lower desired transmit power level by shifting bits in a digital-to-analog converter and setting a transmit gain for a higher transmit power level.

64. The communication system of claim 58 wherein said packet stream comprises a plurality of packets and said control voltage is adjusted from packet to packet.
